(19) United States
(12) Patent Application Publication
(10) Pub. No.: US 2022/0285136 A1
(43) Pub. Date: Sep. 8, 2022

(54) EDGE RING SYSTEMS FOR SUBSTRATE PROCESSING SYSTEMS

(71) Applicant: LAM RESEARCH CORPORATION, Fremont, CA (US)

(72) Inventors: Hui Ling HAN, Alameda, CA (US); Xinwei HUANG, San Jose, CA (US); Alexander Miller PATERSON, San Jose, CA (US); Saravanapriyan SRIRAMAN, Fremont, CA (US); Ann ERICKSON, Lake Oswego, OR (US); Joanna WU, Fremont, CA (US); Seetharaman RAMACHANDRAN, San Jose, CA (US); Christopher KIMBALL, San Jose, CA (US); Aris PEREZ, Fremont, CA (US)

(21) Appl. No.: 17/631,984

(22) PCT Filed: Jul. 30, 2020
(86) PCT No.: PCT/US2020/044168

§ 371 Date: Feb. 1, 2022

Related U.S. Application Data
(60) Provisional application No. 62/882,901, filed on Aug. 5, 2019.

(51) Int. Cl. H01J 37/32; H01L 21/687

(52) U.S. Cl. CPC H01J 37/32642; H01L 21/68735; H01L 21/68742

(57) ABSTRACT

An edge ring system for a substrate processing system includes a top edge ring including an annular body having an inner diameter and an outer diameter. The outer diameter of the top edge ring is smaller than a horizontal opening of a substrate port of the substrate processing system. A first edge ring is arranged below the top edge ring including an annular body having an inner diameter and an outer diameter. The outer diameter of the first edge ring is larger than the substrate port of the substrate processing system. The inner diameter of the first edge ring is smaller than the inner diameter of the top edge ring.

### CROSS REFERENCE TO RELATED APPLICATIONS

This application claims the benefit of U.S. Provisional Application No. 62/882,901, filed on Aug. 5, 2019. The entire disclosure of the application referenced above is incorporated herein by reference.

### FIELD

The present disclosure relates generally to plasma processing systems and more particularly to edge ring systems.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems perform treatments on substrates such as semiconductor wafers. Examples of substrate treatments include deposition, ashing, etching, cleaning and/or other processes. Process gas mixtures may be supplied to the processing chamber to treat the substrate. Plasma may be used to ignite the gases to enhance chemical reactions.

A substrate is arranged on a substrate support during treatment. In some substrate processing systems, an annular edge ring is arranged around the substrate support adjacent to a radially outer edge of the substrate. The edge ring may be used to shape or focus the plasma onto the substrate. During operation, the substrate and an exposed surface of the edge ring is etched by the plasma. As a result, the edge ring wears over time and the effect of the edge ring on the plasma changes.

### SUMMARY

An edge ring system for a substrate processing system includes a top edge ring including an annular body having an inner diameter and an outer diameter. The outer diameter of the top edge ring is smaller than a horizontal opening of a substrate port of the substrate processing system. A first edge ring is arranged below the top edge ring including an annular body having an inner diameter and an outer diameter. The outer diameter of the first edge ring is larger than the substrate port of the substrate processing system. The inner diameter of the first edge ring is smaller than the inner diameter of the top edge ring.

In other features, a lower surface of the top edge ring mates with an upper surface of the first edge ring. A second edge ring is located below the first edge ring and radially outside of a baseplate of the substrate processing system. The second edge ring includes an annular body, an upwardly projecting leg that extends from an upper and radially inner portion of the annular body, and a downwardly projecting leg that extends from a lower and radially outer portion of the annular body.

In other features, a third edge ring is located below the first edge ring and radially outside of the second edge ring. The third edge ring includes an annular body, a radially inwardly projecting leg that extends from an upper portion of the annular body, and a projection extending upwardly from an upper and radially outer surface of the annular body.

In other features, the first edge ring includes an annular recess on a lower and radially outer surface thereof. The projection of the third edge ring mates with the annular recess to define a stepped path.

In other features, an annular seal is arranged below the second edge ring and between the third edge ring and the baseplate of the substrate processing system. The annular seal includes an annular body and a leg extending radially inwardly from a lower portion of the annular body. A diameter at a radially inner surface of the leg is less than an outer diameter of the baseplate. A diameter of a radially inner surface of the annular body of the annular seal is greater than the outer diameter of the baseplate.

In other features, the top edge ring includes a cavity defined by a lower and inner surface of the top edge ring between a radially inner leg and a radially outer leg of the top edge ring and the first edge ring. The lower and inner surface is located vertically higher than a lower surface of the radially outer leg of the top edge ring.

A substrate processing system includes the edge ring system and a substrate support including the baseplate. A seal material is arranged on an outer surface of the baseplate between the baseplate and the annular seal and between the baseplate and the second edge ring. The seal material is arranged between the baseplate and a portion of an upper surface of the leg of the annular seal.

A substrate processing system includes a substrate support including a baseplate. A first edge ring is located radially outside of the baseplate. A second edge ring is located radially outside of the first edge ring. An annular seal includes an annular body and a leg extending radially inwardly from the annular body. The annular seal is arranged below the first edge ring and between the second edge ring and the baseplate of the substrate processing system. A diameter of a radially inner surface of the leg is less than an outer diameter of the baseplate. A diameter of a radially inner surface of the annular body is greater than the outer diameter of the baseplate. A seal material is arranged on an outer surface of the baseplate between the baseplate and the annular seal and between the baseplate and the first edge ring. The seal material is arranged on the baseplate between the baseplate and a portion of an upper surface of the leg of the annular seal.

A substrate support for a substrate processing system includes a baseplate and a vertical bore defined in the baseplate and including an upper opening and a lower opening. A fastener includes a body, a threaded portion, and a head. The fastener is received in the vertical bore and attaches the baseplate to an underlying surface. A plug includes a body received in an upper opening of the vertical bore above the head of the fastener.

In other features, the plug further includes flanged portions extending radially outwardly from the body. The flanged portions extend radially outside of the upper opening. The plug is made of a material selected from a group consisting of ceramic, elastomer, and polytetrafluoroethylene (PTFE).

A substrate support for a substrate processing system includes a baseplate and a vertical bore defined in the baseplate and including an upper opening and a lower opening. An outer guide sleeve includes a first flanged portion and a first cylindrical portion extending from the first flanged portion and defining a first inner bore. The first cylindrical portion of the outer guide sleeve is inserted in the upper opening of the vertical bore with the first flanged portion arranged adjacent to the upper opening of the vertical bore. An inner guide sleeve includes a second flanged portion and a second cylindrical portion extending from the second flanged portion and defining a second inner bore configured to receive a lift pin. The inner guide sleeve is inserted into the bottom opening of the vertical bore and the first inner bore of the outer guide sleeve with the second flanged portions arranged adjacent to the lower opening of the vertical bore.

In other features, the upper opening of the vertical bore has a first diameter that is greater than an outer diameter of the first cylindrical portion and less than an outer diameter of the first flanged portion. The lower opening of the vertical bore has a second diameter that is less than the first diameter, greater than an outer diameter of the second cylindrical portion and less than an outer diameter of the second flanged portion.

In other features, a first diameter of the upper opening is less than a second diameter of the lower opening.

A substrate processing system includes the substrate support. An edge ring is arranged around the substrate support. A lift pin is received in the second inner bore of the inner guide sleeve.

In other features, an underlying surface is located below the baseplate and includes a vertical bore that is vertically aligned with the vertical bore of the baseplate. A guide sleeve includes a third flanged portion and a third cylindrical portion extending from the third flanged portion. The guide sleeve is located in the vertical bore of the underlying surface. The third flanged portions abut the second flanged portion.

In other features, the third flanged portions include a groove and further comprising an O-ring arranged in the groove. The O-ring is biased by the third flanged portion against a horizontal surface of the vertical bore.

A substrate support for a substrate processing system includes a baseplate. A vertical bore is defined in the baseplate and including an upper opening and a lower opening. A supporting surface is located below the baseplate and includes a vertical bore with an upper opening and a lower opening. The vertical bore is vertically aligned with the vertical bore of the baseplate. A guide sleeve includes a flanged portion and a cylindrical portion with an inner bore. The cylindrical portion is located in the vertical bore of the supporting surface. The flanged portion abuts the upper opening of the vertical bore of the supporting surface.

In other features, the flanged portion includes a groove on a lower surface thereof. An O-ring is arranged in the groove and is biased by the flanged portion against a horizontal surface of the vertical bore of the supporting surface.

A substrate processing system includes the substrate support and an edge ring arranged around the substrate support. A lift pin is received in the vertical bore of the baseplate and the vertical bore of the guide sleeve.

A moveable edge ring system for a substrate processing system includes a top edge ring including an annular body. A first edge ring is arranged below the top edge ring including an annular body including a vertical bore. A second edge ring is located below the first edge ring and includes an annular body with a vertical bore with an upper portion having a first diameter and a lower portion having a second diameter that is smaller than the first diameter. A guide sleeve includes an elongate annular body with a vertical bore and has an outer diameter that is less than the first diameter and greater than the second diameter. The vertical bore of the guide sleeve is aligned with the vertical bore of the first edge ring.

In other features, a lift pin is received in the vertical bore to selectively move the top edge ring relative to the first edge ring and the second edge ring.

A substrate processing system includes the moveable edge ring system. A substrate support includes a baseplate with vertical bore aligned with the vertical bore of the second edge ring and the vertical bore of the first edge ring. A guide sleeve for the lift pin is located in the vertical bore of the substrate support.

In other features, the substrate support further includes a heating plate arranged above the baseplate. The annular body of the second edge ring includes a leg projecting radially inwardly from an upper surface of the annular body of the second edge ring above the heating plate and below the first edge ring.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing system according to the present disclosure;

FIG. 2 is a functional block diagram of another example of a substrate processing system according to the present disclosure;

FIG. 3 is a cross-sectional side view of an example of an edge ring system according to the present disclosure;

FIG. 4 is a cross-sectional side view of another example of an edge ring system according to the present disclosure;

FIG. 5 is a cross-sectional side view of another example of an edge ring system according to the present disclosure;

FIG. 6 is a cross-sectional side view of a dual guide sleeve to guide a lift pin of an edge ring system according to the present disclosure;

FIG. 7 is a cross-sectional side view of an edge ring system including a lower guide sleeve for the lift pin according to the present disclosure; and

FIG. 8 is a cross-sectional side view of an edge ring system including an upper guide sleeve for the lift pin according to the present disclosure.

In the drawings, reference numbers may be reused to identify similar and/or identical elements.

### DETAILED DESCRIPTION

During substrate processing, a substrate is arranged on a pedestal such as an electrostatic chuck (ESC), process gases are supplied, and plasma is struck in the processing chamber. Exposed surfaces of components within the processing chamber experience wear due to the plasma.

For example, an annular edge ring is arranged around a radially outer edge of the substrate to shape the plasma. After processing a plurality of substrates, the exposed surface of the edge ring is worn down and sits at a different height relative to the substrate. As a result, the effect of the edge ring on the plasma changes, which alters processing of the substrates. To reduce process changes due to edge ring wear without breaking vacuum, some processing chambers increase the height of the edge ring in situ to compensate for wear. In many of these systems, the height of the edge ring is automatically adjusted based upon the number of cycles and/or the total plasma processing exposure period. Other systems measure the height of the edge ring and adjust the height of the edge ring based on the measured height.

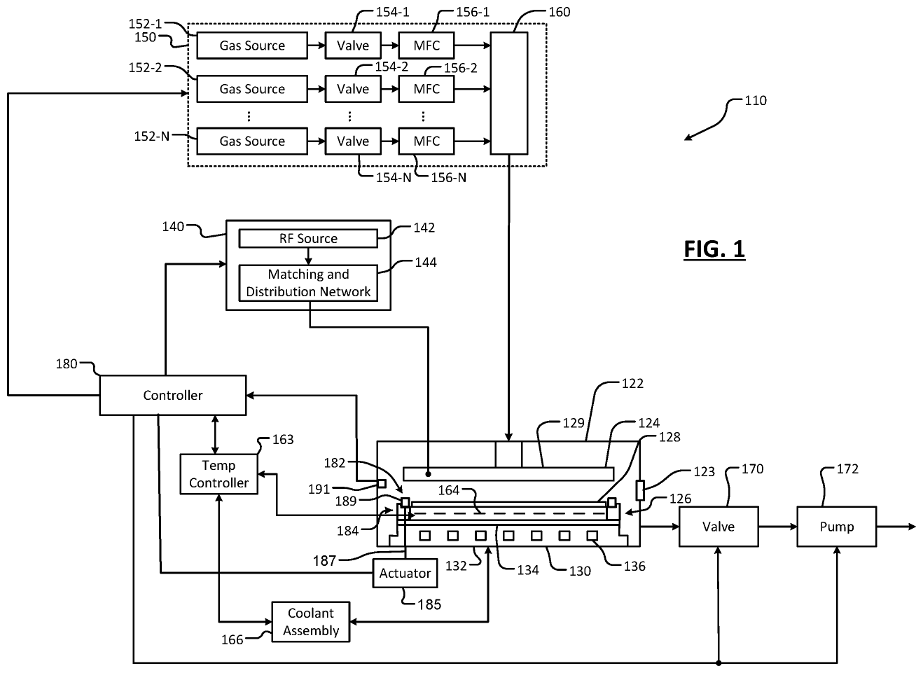

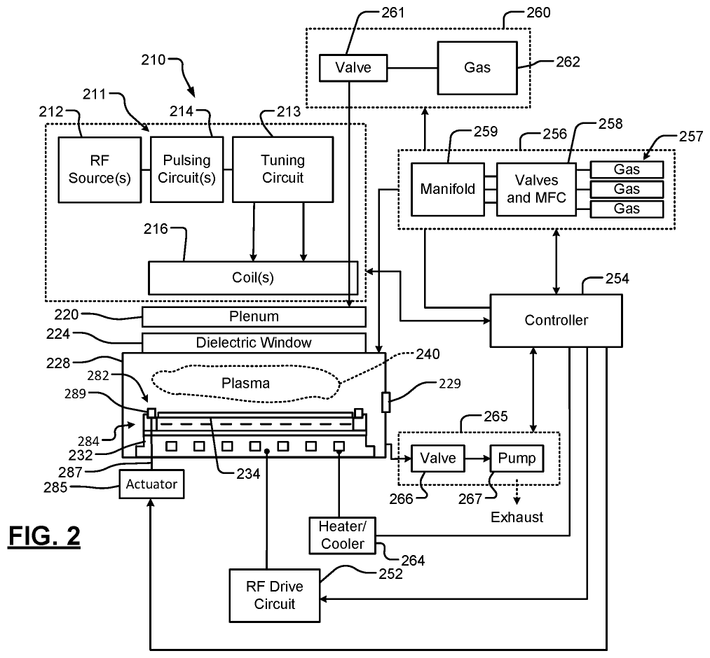

Referring now to FIGS. 1 and 2, examples of plasma processing chambers that use movable edge rings are shown. As can be appreciated, other types of plasma processing chambers can be used. In FIG. 1, an example of a substrate processing system 110 according to the present disclosure is shown. The substrate processing system 110 may be used to perform etching using capacitively coupled plasma (CCP). The substrate processing system 110 includes a processing chamber 122 that encloses other components of the substrate processing system 110 and contains the RF plasma (if used).

When the plasma processing chamber 122 is arranged in a tool, the plasma processing chamber may include a substrate port 123 that can be opened to a vacuum transfer module without breaking vacuum. Generally, the substrate port 123 has a horizontal opening dimension that is slightly greater than a diameter of the substrate to be processed and a vertical opening dimension that is significantly less than the horizontal opening dimension. In some examples, the substrate port 123 is wide enough to deliver and replace a top edge ring. Generally the vertical opening dimension is wide enough to allow a robot end effector to place the substrate on lift pins of the substrate support. The substrate processing system 110 includes an upper electrode 124 and a substrate support 126 such as an electrostatic chuck (ESC). During operation, a substrate 128 is arranged on the substrate support 126.

For example only, the upper electrode 124 may include a gas distribution device 129 such as a showerhead that introduces and distributes process gases. The gas distribution device 129 may include a stem portion including one end connected to a top surface of the processing chamber. A base portion is generally cylindrical and extends radially outwardly from an opposite end of the stem portion at a location that is spaced from the top surface of the processing chamber. A substrate-facing surface or faceplate of the base portion of the showerhead includes a plurality of holes through which precursor, reactants, etch gases, inert gases, carrier gases, other process gases or purge gas flows. Alternately, the upper electrode 124 may include a conducting plate and the process gases may be introduced in another manner.

The substrate support 126 includes a baseplate 130 that acts as a lower electrode. The baseplate 130 supports a heating plate 132, which may correspond to a ceramic multi-zone heating plate. A bonding layer 134 may be arranged between the heating plate 132 and the baseplate 130. In some examples, the bonding layer 134 also provides thermal resistance. The baseplate 130 may include one or more channels 136 for flowing coolant through the baseplate 130.

An RF generating system 140 generates and outputs an RF voltage to one of the upper electrode 124 and the lower electrode (e.g., the baseplate 130 of the substrate support 126). The other one of the upper electrode 124 and the baseplate 130 may be DC grounded, AC grounded or floating. For example only, the RF generating system 140 may include an RF source 142 that generates RF plasma power that is fed by a matching and distribution network 144 to the upper electrode 124 or the baseplate 130. In other examples, the plasma may be generated inductively or remotely.

A gas delivery system 150 includes one or more gas sources 152-1, 152-2, . . . , and 152-N (collectively gas sources 152), where N is an integer greater than zero. The gas sources 152 are connected by valves 154-1, 154-2, . . . , and 154-N (collectively valves 154) and mass flow controller (MFCs) 156-1, 156-2, . . . , and 156-N (collectively MFCs 156) to a manifold 160. Secondary valves may be used between the MFCs 156 and the manifold 160. In some examples, secondary valves (not shown) are arranged between the MFCs 156 and the manifold 160. While a single gas delivery system 150 is shown, two or more gas delivery systems can be used.

A temperature controller 163 may be connected to a plurality of thermal control elements (TCEs) 164 arranged in the heating plate 132. The temperature controller 163 may be used to control the plurality of TCEs 164 to control a temperature of the substrate support 126 and the substrate 128. The temperature controller 163 may communicate with a coolant assembly 166 to control coolant flow through the channels 136. For example, the coolant assembly 166 may include a coolant pump, a reservoir and/or one or more temperature sensors. The temperature controller 163 operates the coolant assembly 166 to selectively flow the coolant through the channels 136 to cool the substrate support 126.

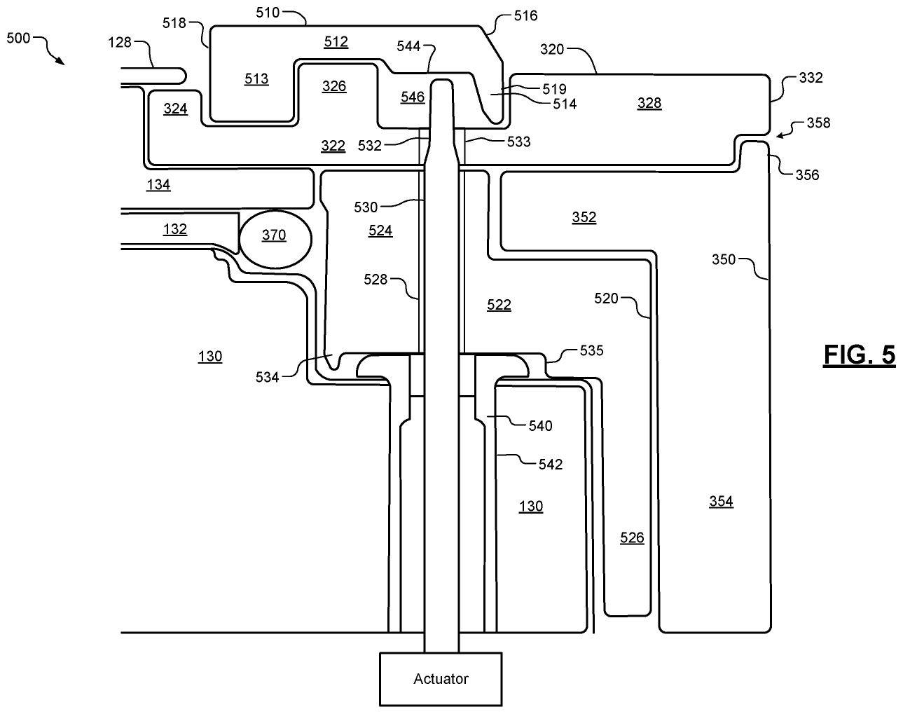

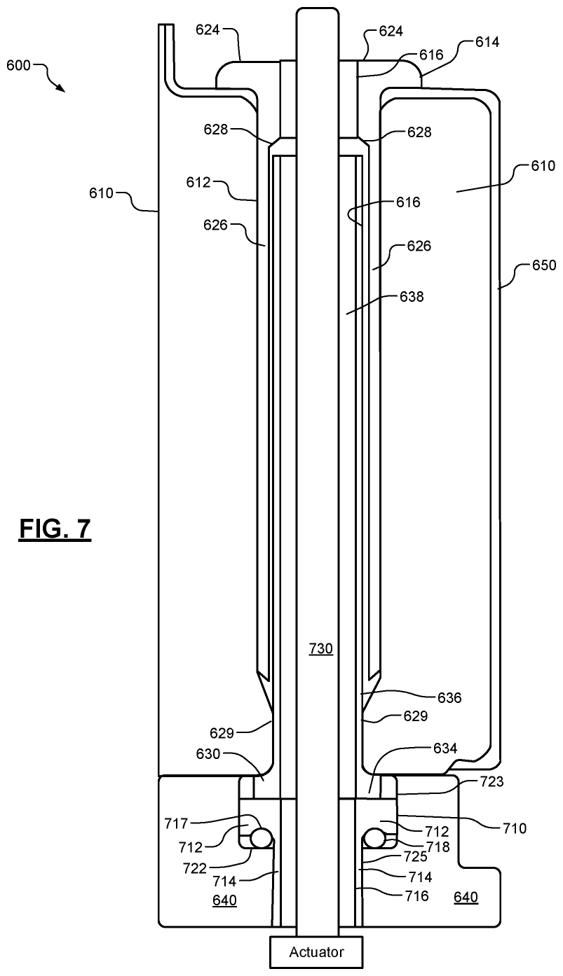

A valve 170 and pump 172 may be used to evacuate reactants from the processing chamber 122. A system controller 180 may be used to control components of the substrate processing system 110. An edge ring system 182 including one or more edge rings may be arranged radially outside of the substrate 128 during plasma processing. An edge ring height adjustment system 184 includes one or more lift pins (shown in FIGS. 5 and 7) that may be used to adjust a height of one or more of the edge rings of the edge ring system 182 relative to the substrate 128 as will be described further below. In some examples, one or more of the edge rings of the edge ring system 182 can also be raised by the lift pins, removed by a robot end effector and replaced with another edge ring without breaking vacuum.

For example, the system controller 180 controls an actuator 185, which controls a vertical position of a lift pin 187 that biases a bottom surface of an edge ring 189. In this example, the system controller 180 senses a height of the edge ring 189 using a sensor 191. In some examples, the sensor 191 includes optical, laser, piezo, ultrasound or other type of sensor. The system controller 180 adjusts the position of the edge ring 189 based sensed height of the edge ring 189.

In FIG. 2, an example of a substrate processing system 210 according to the present disclosure is shown. The substrate processing system 210 uses inductively coupled plasma to perform etching. The substrate processing system 210 includes a coil driving circuit 211. A pulsing circuit 214 may be used to pulse the RF power on and off or vary an amplitude or level of the RF power. The tuning circuit 213 may be directly connected to one or more inductive coils 216. The tuning circuit 213 tunes an output of the RF source 212 to a desired frequency and/or a desired phase, matches an impedance of the coils 216 and splits power between the coils 216.

In some examples, a plenum 220 may be arranged between the coils 216 and a dielectric window 224 to control the temperature of the dielectric window 224 with hot and/or cold air flow. The dielectric window 224 is arranged along one side of a processing chamber 228. The processing chamber 228 further comprises a substrate support 232. A substrate port 229 is arranged on one side of the processing chamber. In some examples, the substrate port 229 has a horizontal width sufficient to allow the top edge ring to be delivered and replaced without breaking vacuum.

The substrate support 232 may include an electrostatic chuck (ESC), or a mechanical chuck or other type of chuck. Process gas is supplied to the processing chamber 228 and plasma 240 is generated inside of the processing chamber 228. The plasma 240 etches an exposed surface of the substrate 234 and causes wear to the edge ring. A drive circuit 252 (such as one of those described below) may be used to provide an RF bias to an electrode in the substrate support 232 during operation.

A gas delivery system 256 may be used to supply a process gas mixture to the processing chamber 228. The gas delivery system 256 may include process and inert gas sources 257, a gas metering system 258 such as valves and mass flow controllers (e.g as described above), and a manifold 259. A gas delivery system 260 may be used to deliver gas 262 via a valve 261 to the plenum 220. The gas may include cooling gas (air) that is used to cool the coils 216 and the dielectric window 224. A heater/cooler 264 may be used to heat/cool the substrate support 232 to a predetermined temperature. An exhaust system 265 includes a valve 266 and pump 267 to remove reactants from the processing chamber 228 by purging or evacuation.

A controller 254 may be used to control the etching process. The controller 254 monitors system parameters and controls delivery of the gas mixture, striking, maintaining and extinguishing the plasma, removal of reactants, supply of cooling gas, and so on.

An edge ring system 282 including one or more edge rings may be located radially outside of the substrate 234 during plasma processing. A height adjustment system 284 includes one or more lift pins shown below. The height adjustment system 284 may be used to adjust a height of one or more edge rings of the edge ring system 282. In addition, the edge ring may optionally be removed when worn and replaced without breaking vacuum (e.g. when a vacuum transfer module is used). The controller 254 may be used to control the height adjustment system 284. For example, the controller 254 controls an actuator 285, which controls a vertical position of a lift pin 287 that biases a bottom surface of an edge ring 289. In this example, the controller 254 adjusts the position of the edge ring 289 based on an RF exposure period and/or number of RF cycles.

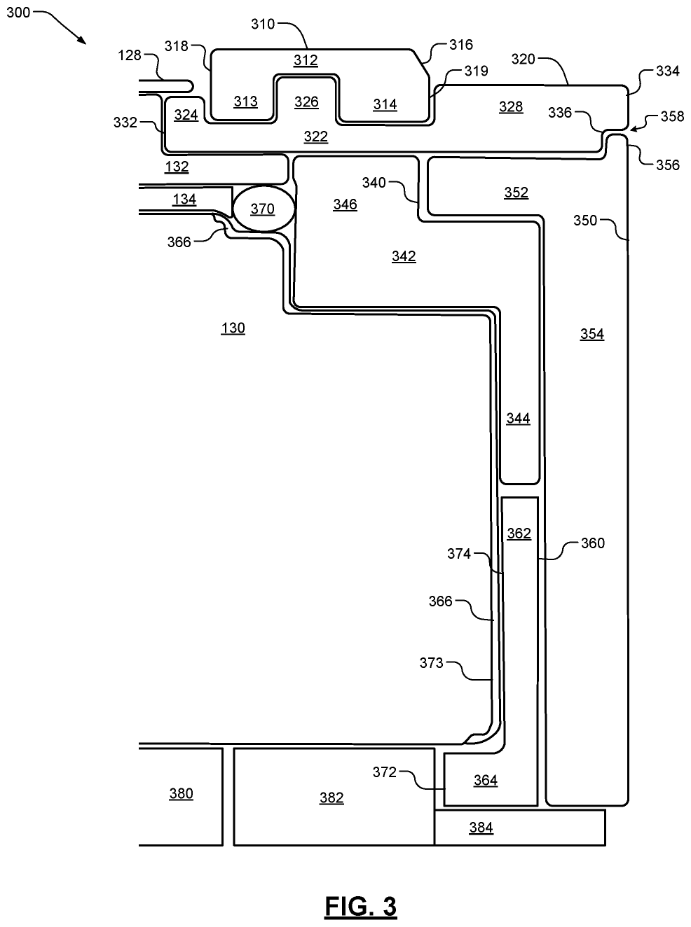

Referring now to FIG. 3, an edge ring system 300 according to the present disclosure is shown. The edge ring system 300 includes an assembly of edge rings including a top edge ring 310, an edge ring 320, an edge ring 340 and an edge ring 350. As shown, the top edge ring 310 has an inverted “U”-shaped cross section. The top edge ring 310 includes an annular body 312 connected to a radially inner leg 313 and a radially outer leg 314. In some examples, the top edge ring 310 includes a radially inner edge 318 and a radially outer edge 319. The top edge ring 310 includes a sloped surface 316 that slopes at an angle from a top surface of the top edge ring 310 to the radially outer edge 319. In some examples, the angle is an acute angle, although other angles can be used.

The top edge ring 310 has an upper surface that is located radially outside of the substrate and is raised relative to the substrate. The top edge ring 310 is directly exposed to plasma and the other edge rings are shielded by the top edge ring 310 or located in radially outer locations subjected to less plasma exposure and wear. Therefore, the top edge ring 310 wears faster than the other edge rings. In some examples, the top edge ring 310 is removed after a predetermined amount of wear. Generally the other edge rings remain for a longer service period prior to replacement. While a specific number of edge rings are shown in the various embodiments, additional or fewer edge rings can be used. For example, two or more of the edge rings can be combined into one edge ring or one of the edge rings can be split into two or more edge rings. Additional edge rings can be added to address coupling, wear, or structural support or for other purposes.

An edge ring 320 has an “E”-shaped cross section and is located below the top edge ring 310 and includes an annular body 322 including a radially inner leg 324, a middle leg 326, and an outer leg 328 that extend upwardly from the annular body 322. The middle leg 326 is located between the radially inner leg 313 and the radially outer leg 314 of the top edge ring 310. The radially inner leg 324 is located radially inwardly of the radially inner leg 313 of the top edge ring 310 and below the substrate 128. The edge ring 320 includes a radially inner edge 332 and a radially outer edge 334. The edge ring 320 further includes an annular recess 336 located on a lower and radially outer surface of the edge ring 320.

In some examples, the radially outer edge 319 of the top edge ring 310 has a diameter that is smaller than a diameter of the substrate port 229 into the processing chamber. In some examples, the radially outer edge 334 of the edge ring 320 is greater than the diameter of the substrate port 229 into the processing chamber. In some examples, a diameter of the radially inner edge 332 of the edge ring 320 is less than a diameter of the radially inner edge of the top edge ring 310. The top edge ring 310 can be removed through the substrate port without breaking vacuum whereas the edge ring 320 cannot be removed through the substrate port (without breaking vacuum if a vacuum transfer module is used). The smaller inner diameter of the radially inner edge 332 and the larger outer diameter of the radially outer edge 334 of the edge ring 320 blocks particles, which tends to reduce defects.

An edge ring 340 is located beneath the top edge ring 310 and the edge ring 320. The edge ring 340 includes an annular body 342. An upwardly projecting leg 346 extends from an upper and radially inner surface of the annular body 342. A downwardly projecting leg 344 extends from a lower and radially outer surface of the annular body 342.

An edge ring 350 is located radially outside of the edge ring 340 and below the edge ring 320. The edge ring 350 includes an annular body 354. A radially inwardly projecting leg 352 extends from an upper portion of the annular body 354. A projection 356 extends upwardly from an upper and radially outer surface thereof. The annular recess 336 of the edge ring 320 and the projection 356 of the edge ring 350 mate to define a serpentine or stepped path 358.

An annular seal 360 is arranged below the edge ring 340 and between the baseplate 130 and the edge ring 350. The annular seal 360 has an “L”-shaped cross section. The annular seal 360 includes an annular body 362 and a leg 364 that projects radially inwardly from a lower portion of the annular body 362. In some examples, a seal material 366 is attached to an outer surface of the baseplate 130 from an edge of the bonding layer 134 to a bottom edge of the baseplate 130.

In some examples, the seal material 366 and/or the annular seal 360 is made of a material such as elastomer, polytetrafluoroethylene (PTFE), ceramic or another material. The leg 364 of the annular seal 360 acts as a retention feature and limits vertical movement of the annular seal 360 during plasma processing. Without the leg 364, the annular seal 360 tends to move upwardly over time. In addition, the annular seal 360 prevents plasma from entering a terminal region of the substrate support. In some examples, a radially inner surface 372 of the leg 364 has a diameter that is less than a radially outer surface 373 of the baseplate 130. In some examples, a radially inner surface 374 of the annular body 362 is greater than the radially outer surface 373 of the baseplate 130.

The baseplate 130 is located above baseplate supports 380, 382 and 384. The baseplate support 384 defines a gap below a lower surface of the baseplate 130 to receive the leg 364 of the annular seal 360. An annular seal 370 is arranged radially outside of the bonding layer 134 below the heating plate 132 and above the baseplate 130. The annular seal 370 protects the bonding layer 134 from plasma attack and/or other contaminants.

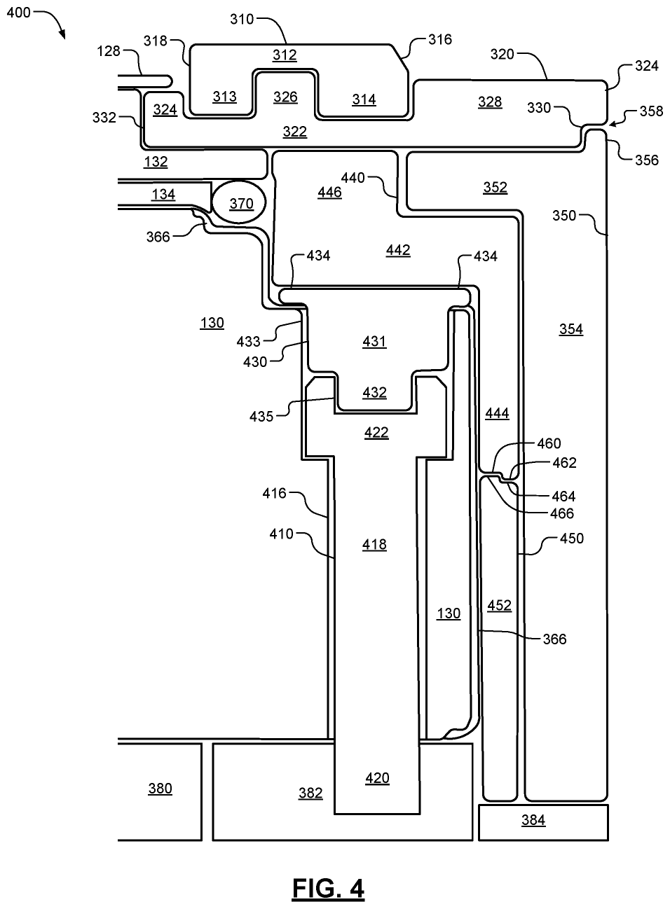

In some examples, the edge ring system 300 includes a lift pin (shown in embodiments below) that selectively lifts the top edge ring 310 relative to the edge rings 320, 330, 340 and 350. The edge rings 320 and 340 and the baseplate 130 may include a vertical bore (for example as shown in FIG. 4) to allow the lift pin to move vertically as will be shown in various embodiments below.

Referring now to FIG. 4, an edge ring system 400 is shown. In some examples, the baseplate 130 defines a vertical bore 416 to receive fasteners 410 including a body 418, a threaded portion 420, and a head 422. The fasteners 410 are circumferentially spaced around the baseplate 130 and attach the baseplate 130 to an underlying surface such as the baseplate supports 380, 382 and/or 384. In some examples, the fasteners 410 are threaded into threaded bores in the baseplate support 382.

A plug 430 includes a cylindrical body 431 having a diameter that is approximately equal to an upper opening 433 in the vertical bore 416. A lower cylindrical portion 432 of the plug 430 has a narrower diameter that is arranged in an opening 435 in a top surface of the fastener 410. An upper surface of the plug 430 includes flanges 434 that extend radially outwardly from the cylindrical body 431. The flanges 434 have a diameter that is larger than the upper opening 433 of the vertical bore 417.

In some examples, the plug 430 is made of ceramic, elastomer, polytetrafluoroethylene (PTFE), or other plasma resistant material. As can be appreciated, the plug 430 can be used in other locations.

An edge ring 440 includes an annular body 442 including a downwardly projecting leg 444 extending from a radially outer edge of the annular body 442. An upwardly projecting leg 446 extends upwardly from a radially inner edge the annular body 442. An edge ring 450 includes an annular body 452 that is arranged below the downwardly projecting leg 444 of the edge ring 440.

The downwardly projecting leg 444 of the edge ring 440 includes a projection 462 and an annular recess 460 located on a lower surface thereof. The annular body 452 of the edge ring 450 includes a projection 466 and an annular recess 464 located on an upper surface thereof. The projection 462 and the annular recess 460 of the edge ring 440 mate with the projection 466 and the annular recess 464 of the edge ring 450 to provide a stepped, serpentine or labyrinth path to prevent or significantly reduce arcing. As can be appreciated, a similar stepped arrangement can be used with the annular seal 360 and the edge ring 340 described above.

Referring now to FIG. 5, an edge ring system 500 includes a top edge ring 510 having an inverted “U”-shape. The top edge ring 510 includes an annular body 512 connected to a radially inner leg 513 and a radially outer leg 514. The top edge ring 510 includes radially inner edge 518 and a radially outer edge 519. The top edge ring 510 includes a sloped surface 516 that slopes at an acute angle from a top surface of the top edge ring 510 to the radially outer edge 519. A lower and inner surface 544 (located between the radially outer leg 514 and the radially inner leg 513) of the top edge ring 510 defines a cavity 546 with respect to the edge ring 320. The lower and inner surface 544 acts to center and retain the top edge ring 570 when lifted by one or more lift pins.

In some examples, the lower and inner surface 544 extends parallel to a plane including the substrate 128 (at a location that is spaced from the edge ring 320 and slightly below an upper surface of the middle leg 326 of the edge ring 320). The radially outer leg 514 extends in close proximity to the edge ring 320 between the middle leg 326 and the outer leg 328. The edge ring 320 includes a vertical bore 533 to allow a lift pin to pass there through.

An edge ring 520 includes an annular body 522 and an upwardly projecting leg 524 extending from a radially inner surface of the annular body 522. A downwardly projecting leg 526 extends downwardly from a lower and radially outer surface of the annular body 522. A vertical bore 528 is located in the upwardly projecting leg 524 of the edge ring 520 allow a lift pin 530 to move vertically. In some examples, the lift pin 530 includes a tapered upper portion 532. The edge ring 520 defines a projection 534 and an annular recess 535 to provide clearance for a guide sleeve 540 arranged in a vertical bore 542 in the baseplate 130. In some examples, the lift pin 530 is coated with ceramic or another material. The vertical bore 542 is aligned with vertical bores 533 and 528.

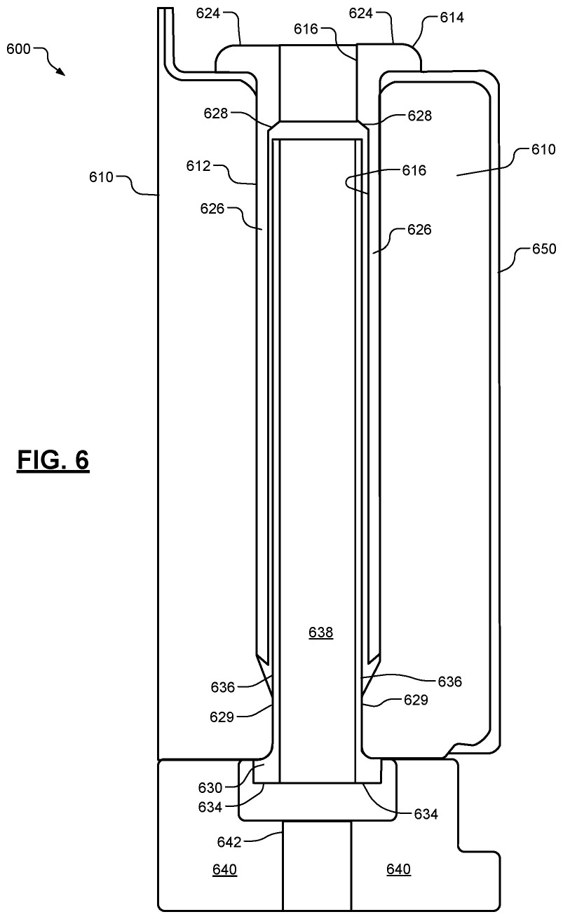

Referring now to FIG. 6, an edge ring system 600 includes a structure 610 such as a baseplate, an edge ring or another type of supporting structure. The structure 610 defines a vertical bore 612. An outer guide sleeve 614 is inserted in the vertical bore 612 from an upper opening thereof. The outer guide sleeve 614 defines an inner bore 616 to receive a lift pin (not shown). The outer guide sleeve 614 includes flanged portions 624 that extend radially outwardly beyond the upper opening of the vertical bore 612. The outer guide sleeve 614 further includes a cylindrical portion 626 that extends downwardly in the vertical bore 612 near a bottom opening of the vertical bore 612. In some examples, the inner bore 616 widens radially at 628 below the opening of the vertical bore 612.

In some examples, the vertical bore 612 includes a lower portion 629 (arranged below the cylindrical portion 626 of the outer guide sleeve 614) that has a smaller diameter than a diameter of an upper portion of the vertical bore 612. An inner guide sleeve 630 is inserted into the inner bore 616 of the outer guide sleeve 650 from a bottom opening thereof. The inner guide sleeve 630 includes flanged portions 634 that extend radially beyond the bottom opening of the vertical bore 612. The inner guide sleeve 630 further includes a cylindrical portion 636 extending from the flanged portions 634 and defining an inner bore 638. The inner guide sleeve 630 is received within the inner bore 616 of the outer guide sleeve 614.

The structure 610 is arranged above a supporting surface 640 that defines a vertical bore 642 that aligns with the inner bore 638 of the inner guide sleeve 630. The lift pin (not shown) is received by the vertical bore 642 and the inner bore 638.

Referring now to FIG. 7, a lower guide sleeve 710 for guiding a lift pin 730 is shown to include flanged portions 712 that extend radially outwardly from a cylindrical portion 714 that defines an inner bore 716. Lower surfaces of the flanged portion 712 include a groove 717 to engage an upper surface of an O-ring 718. The O-ring 718 is biased by the lower guide sleeve 710 against an upper surface 722 of an upper bore portion 723 of the supporting surface 640. A lower bore portion 725 is located below the upper bore portion 723 and has a smaller diameter than the upper bore portion 723. A lift pin 730 is reciprocally received in the inner bore 716 of the lower guide sleeve 710 and inner cavities of the lower guide sleeve and the upper guide sleeve. The lower guide sleeve prevents or significantly reduces arcing in a terminal junction region.

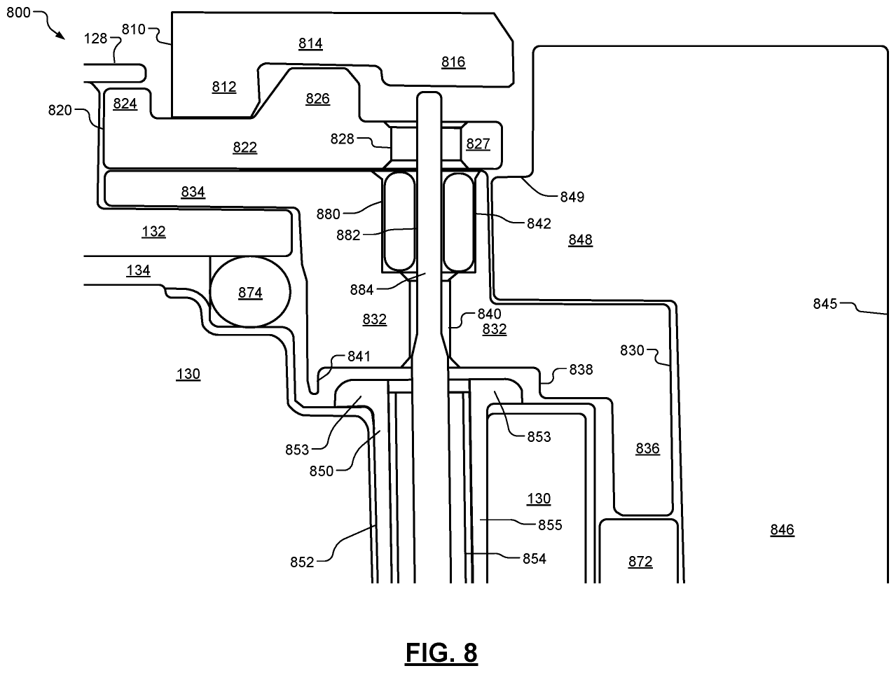

Referring now to FIG. 8, an edge ring system 800 includes an upper guide sleeve for the lift pin is shown. A top edge ring 810 has an inverted “U”-shape and includes an annular body 814, a radially inner leg 812 and a radially outer leg 816. An edge ring 820 is arranged below the edge ring 810 and includes an annular body 822, a radially inner leg 824 projecting upwardly from the annular body 822 and a middle leg 826 projecting upwardly from a middle portion of the annular body 822. A leg 827 projects radially outwardly from the annular body 822 and defines a vertical bore 828 to receive a lift pin.

An edge ring 830 includes an annular body 832 including a radially inwardly projecting leg 834 extending from an upper surface of the annular body 832 and a downwardly projecting leg 836 extending downwardly from a lower and radially outer surface of the annular body 832. The annular body 832 further defines an annular recess 838 and a projection 841 are configured to receive and surround an upper portion of a guide sleeve 850. A projection 841 projects downwardly from a radially inner and lower surface of the annular body 832 of the edge ring 830. The annular body 832 further includes an upper bore 840 that is aligned with a lower bore 842. The lower bore 842 has a larger diameter than the upper bore 840.

An edge ring 845 is located radially outside of the edge rings 810, 820 and 830. The edge ring 845 includes an annular body 846 having a radially inwardly projecting portion 848 projecting from a mid portion of the annular body 846. An annular recess 849 is located above the radially inwardly projecting portion 848 and is configured to receive the edge rings 810 and 820.

The guide sleeve 850 is arranged in a vertical bore 852 in the baseplate 130. The guide sleeve 850 includes flanges 853 extending radially beyond an upper opening of the vertical bore 852. The guide sleeve 850 further includes a cylindrical portion 855 that extends downwardly from the flanges 853 into and along the vertical bore 852. The guide sleeve 850 defines an inner bore 854. In some examples, a ceramic band 872 is arranged between the baseplate 130 and the annular body 846 of the edge ring 845 below the edge ring 830.

An upper guide sleeve 880 is received in the bore 842. The upper guide sleeve 880 has an elongated donut shape and includes a central vertical bore 882. A lift pin 884 is received in the inner bore 854 of the guide sleeve 850, the upper bore 840 and the lower bore 842 of the edge ring 830, the central vertical bore 882 of the upper guide sleeve 880, and the vertical bore 828 of the edge ring 820. The upper guide sleeve 880 reduces arcing.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. An edge ring system for a substrate processing system comprising:
a top edge ring including an annular body having an inner diameter and an outer diameter,
wherein the outer diameter of the top edge ring is smaller than a horizontal opening of a substrate port of the substrate processing system; and
a first edge ring arranged below the top edge ring including an annular body having an inner diameter and an outer diameter,
wherein the outer diameter of the first edge ring is larger than the substrate port of the substrate processing system and wherein the inner diameter of the first edge ring is smaller than the inner diameter of the top edge ring.

2. The edge ring system of claim 1, wherein a lower surface of the top edge ring mates with an upper surface of the first edge ring.

3. The edge ring system of claim 1, further comprising a second edge ring located below the first edge ring and radially outside of a baseplate of the substrate processing system.

4. The edge ring system of claim 3, wherein the second edge ring includes:
an annular body;
an upwardly projecting leg that extends from an upper and radially inner portion of the annular body; and
a downwardly projecting leg that extends from a lower and radially outer portion of the annular body.

5. The edge ring system of claim 3, further comprising a third edge ring located below the first edge ring and radially outside of the second edge ring.

6. The edge ring system of claim 5, wherein the third edge ring includes:
an annular body;
a radially inwardly projecting leg that extends from an upper portion of the annular body; and
a projection extending upwardly from an upper and radially outer surface of the annular body.

7. The edge ring system of claim 6, wherein:
the first edge ring includes an annular recess on a lower and radially outer surface thereof; and
the projection of the third edge ring mates with the annular recess to define a stepped path.

8. The edge ring system of claim 5, further comprising an annular seal arranged below the second edge ring and between the third edge ring and the baseplate of the substrate processing system.

9. The edge ring system of claim 8, wherein the annular seal includes an annular body and a leg extending radially inwardly from a lower portion of the annular body.

10. The edge ring system of claim 9, wherein a diameter at a radially inner surface of the leg is less than an outer diameter of the baseplate.

11. The edge ring system of claim 10, wherein a diameter of a radially inner surface of the annular body of the annular seal is greater than the outer diameter of the baseplate.

12. The edge ring system of claim 1, wherein:
the top edge ring includes a cavity defined by a lower and inner surface of the top edge ring between a radially inner leg and a radially outer leg of the top edge ring and the first edge ring; and
the lower and inner surface is located vertically higher than a lower surface of the radially outer leg of the top edge ring.

13. The edge ring system of claim 9, further comprising a seal material arranged on an outer surface of a baseplate of a substrate support between the baseplate and the annular seal and between the baseplate and the second edge ring.

14. The edge ring system of claim 13, wherein the seal material is arranged between the baseplate and a portion of an upper surface of of the annular seal.

15. The edge ring system of claim 3, further comprising:
a vertical bore defined in the baseplate and including an upper opening and a lower opening;
a fastener including a body, a threaded portion, and a head,
wherein the fastener is received in the vertical bore and attaches the baseplate to an underlying surface; and
a plug including a body, wherein the body of the plug is received in an upper opening of the vertical bore above the head of the fastener.

16. The edge ring system of claim 15, wherein:
the plug further includes a flanged portion extending radially outwardly from the body; and
the flanged portion extends radially outside of the upper opening.

17. The edge ring system of claim 15, wherein the plug is made of a material selected from a group consisting of ceramic, elastomer, and polytetrafluoroethylene (PTFE).

18. The edge ring system of claim 1, wherein the top edge ring is moveable relative to the first edge ring.

19. The edge ring system of claim 18, further comprising a lift pin received in a vertical bore through the first edge ring to selectively move the top edge ring relative to the first edge ring.

20. The edge ring system of claim 19, further comprising a second edge ring, wherein the lift pin is further configured to selectively move the top edge ring relative to the second edge ring.

21. The edge ring system of claim 19, further comprising:
an actuator configured to bias the lift pin; and
a controller configured to cause the actuator to adjust a position of the lift pin in response to at least one of an output of a sensor and a predetermined period that the top edge ring is exposed to plasma.

22. A substrate support for a substrate processing system comprising:
a baseplate;
a vertical bore defined in the baseplate and including an upper opening and a lower opening;
an outer guide sleeve including a first flanged portion and a first cylindrical portion extending from the first flanged portion and defining a first inner bore,
wherein the first cylindrical portion of the outer guide sleeve is inserted in the upper opening of the vertical bore with the first flanged portion arranged adjacent to the upper opening of the vertical bore; and
an inner guide sleeve including a second flanged portion and a second cylindrical portion extending from the second flanged portion and defining a second inner bore configured to receive a lift pin,
wherein the inner guide sleeve is inserted into a bottom opening of the vertical bore and the first inner bore of the outer guide sleeve with the second flanged portion arranged adjacent to the lower opening of the vertical bore.

23. The substrate support of claim 22, wherein the upper opening of the vertical bore has a first diameter that is greater than an outer diameter of the first cylindrical portion and less than an outer diameter of the first flanged portion.

24. The substrate support of claim 23, wherein the lower opening of the vertical bore has a second diameter that is less than the first diameter, greater than an outer diameter of the second cylindrical portion and less than an outer diameter of the second flanged portion.

25. The substrate support of claim 22, wherein a first diameter of the upper opening is less than a second diameter of the lower opening.

26. The substrate support of claim 22, further comprising:
an edge ring arranged around the substrate support; and
a lift pin received in the second inner bore of the inner guide sleeve.

27. The substrate support of claim 22, further comprising:
an underlying surface located below the baseplate and including a vertical bore that is vertically aligned with the vertical bore of the baseplate; and
a guide sleeve including a third flanged portion and a third cylindrical portion extending from the third flanged portion,
wherein the guide sleeve is located in the vertical bore of the underlying surface and wherein the third flanged portion abuts the second flanged portion.

28. The substrate support of claim 27, wherein the third flanged portion includes a groove and further comprising an O-ring arranged in the groove.

29. The substrate processing system of claim 28, wherein the O-ring is biased by the third flanged portion against a horizontal surface of the vertical bore.
